(19) United States
(12) Patent Application Publication
(10) Pub. No.: US 2024/0155886 A1
(43) Pub. Date: May 9, 2024

(54) DISPLAY DEVICE

(71) Applicant: Samsung Display Co., LTD., Yongin-si (KR)

(72) Inventors: Gwui-Hyun PARK, Yongin-si (KR); Koichi SUGITANI, Yongin-si (KR); HOKYUNG JANG, Yongin-si (KR); Sae Hee HAN, Yongin-si (KR)

(73) Assignee: Samsung Display Co., LTD., Yongin-si (KR)

(21) Appl. No.: 18/486,161

(22) Filed: Oct. 13, 2023

(30) Foreign Application Priority Data
Oct. 14, 2022 (KR) 10-2022-0132576

(51) Int. Cl. H10K 59/126; H01L 29/786; H10K 85/20; H10K 85/60

(52) U.S. Cl. CPC H10K 59/126; H01L 29/78672; H01L 29/7869; H10K 85/20; H10K 85/621; H10K 2102/351

(57) ABSTRACT

A display device includes: a substrate; a transistor including a semiconductor layer disposed on the substrate; and a light emitting device electrically connected to the transistor, wherein the substrate includes a first organic layer, a first barrier layer, a second organic layer, a second barrier layer, and a shielding layer, the shielding layer includes a compound represented by Chemical Formula 1 below, and the shielding layer is disposed between the second barrier layer and the semiconductor layer.

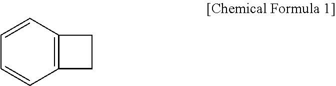

### CROSS-REFERENCE TO RELATED APPLICATION

This application claims priority to and the benefit of Korean Patent Application No. 10-2022-0132576 under 35 U.S.C. § 119, filed in the Korean Intellectual Property Office on Oct. 14, 2022, the entire contents of which are incorporated herein by reference.

### BACKGROUND

### 1. Technical Field

The disclosure relates to a display device having improved light reliability.

### 2. Description of the Related Art

As information society develops, demands for display devices for displaying images are increasing in various forms. A display device may include a display crystal display (LCD), a plasma display panel (PDP), an organic light emitting diode display (OLED), and/or a micro light emitting diode display.

The display device may include a light emitting diode and thin film transistors electrically connected to the light emitting diode. The thin film transistors may include a thin film transistor including a polycrystalline silicon or a thin film transistor including an oxide. The thin film transistor including the polycrystalline silicon may supply a stable driving current, and the thin film transistor including the oxide may have a fast turn-on operation characteristic and an excellent off-current characteristic.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device in which light reliability of a semiconductor may be improved by positioning an organic film shielding layer between a substrate and the semiconductor.

An embodiment of the disclosure provides a display device including: a substrate; at least one transistor including a semiconductor layer disposed on the substrate; and a light emitting device electrically connected to the at least one transistor, wherein the substrate may include a first organic layer, a first barrier layer, a second organic layer, a second barrier layer, and a shielding layer, the shielding layer may include a compound represented by Chemical Formula 1 below, and the shielding layer may be disposed between the second barrier layer and the semiconductor layer.

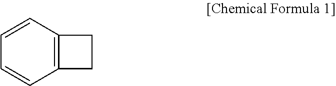

A thickness of the shielding layer may be about 0.5 μm to about 10 μm.

The first organic layer and the second organic layer each may include polyimide.

The first barrier layer and the second barrier layer each may include an inorganic material.

The first organic layer, the first barrier layer, the second organic layer, the second barrier layer, and the shielding layer may be sequentially stacked each other on the substrate, and the shielding layer may be disposed between the semiconductor layer and any one of the first organic layer, the first barrier layer, the second organic layer, and the second barrier layer.

The semiconductor layer may include an oxide semiconductor.

The semiconductor layer may include polycrystalline silicon.

The at least one transistor may further include a plurality of transistors, a first of the transistors may include an oxide semiconductor, and a first of the transistors may include a polycrystalline semiconductor.

The substrate may further include a base layer, and the base layer may include glass.

The shielding layer may directly contact the semiconductor layer.

Another embodiment of the disclosure provides a display device including: a substrate; at least one transistor including a semiconductor layer disposed on the substrate; and a light emitting device electrically connected to the transistor, wherein the substrate may include a first organic layer, a first barrier layer, a second organic layer, a shielding layer, and a second barrier layer, the shielding layer may include a compound represented by Chemical Formula 1 below, and the shielding layer may be disposed between the second organic layer and the second barrier layer.

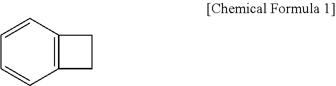

A thickness of the shielding layer may be about 0.5 μm to about 10 μm.

The first organic layer and the second organic layer each may include polyimide.

The first barrier layer and the second barrier layer each may include an inorganic material.

The first organic layer, the first barrier layer, the second organic layer, the shielding layer, and the second barrier layer may be sequentially stacked each other on the substrate, and the second barrier layer may be disposed between the semiconductor layer and any one of the first organic layer, the first barrier layer, the second organic layer, and the second barrier layer.

The semiconductor layer may include an oxide semiconductor.

The semiconductor layer may include polycrystalline silicon.

The at least one transistor may further include a plurality of transistors, a first or more of the transistors may include an oxide semiconductor, and a second or more of the transistors may include a polycrystalline semiconductor.

The base layer may include glass.

The second barrier layer may directly contact the semiconductor layer.

According to the embodiments, light reliability of a semiconductor in a display device may be improved by positioning an organic film shielding layer between a substrate and the semiconductor.

### BRIEF DESCRIPTION OF THE DRAWINGS

The above and other aspects and features of the disclosure will become more apparent by describing in detail embodiments thereof with reference to the attached drawings, in which:

FIG. 1 schematically illustrates a schematic cross-sectional view of a display device according to an embodiment.

FIG. 2 illustrates a weight by percentage (%) relative to a temperature of benzocyclobutene.

FIG. 3 illustrates a display device according to an embodiment.

FIG. 4 illustrates a circuit diagram of an equivalent circuit of a pixel of a display device according to an embodiment.

FIG. 5 illustrates a top plan view of a display device according to an embodiment, and

FIG. 6 illustrates a schematic cross-sectional view taken along a line VI-VI′ of FIG. 5.

FIG. 7 to FIG. 12 illustrate top plan views sequentially showing a display device according to a manufacturing process according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

To clearly describe the embodiments, parts that are irrelevant to the description are omitted, and like numerals refer to like or similar constituent elements throughout the specification.

In the drawings, sizes, thicknesses, ratios, and dimensions of the elements may be exaggerated for ease of description and for clarity. Like numbers and/or reference characters refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

It will be understood that when an element (or a region, a layer, a portion, or the like) is referred to as “being on”, “disposed on”, “connected to” or “coupled to” another element in the specification, it can be directly disposed on, connected or coupled to another element mentioned above, or intervening elements may be disposed therebetween. It will be understood that the terms “connected to” or “coupled to” may include a physical or electrical connection or coupling.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof. The terms “overlap”, “overlapping”, or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or “to not overlap” another element, this may include that the elements are spaced apart from each other, offset from each other, or set aside from each other or any other suitable term as would be appreciated and understood by those of ordinary skill in the art.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In case that an element is referred to as being “in contact” or “contacted” or the like to another element, the element may be in “electrical contact” or in “physical contact” with another element; or in “indirect contact” or in “direct contact” with another element.

A description that a component is “configured to” perform a specified operation may be defined as a case where the component is constructed and arranged with structural features that can cause the component to perform the specified operation.

A reference to a “region” of a transistor can refer to a source region or a drain region, as appropriate. For example, a description that a first transistor has a first region electrically connected to a second region of a second transistor can mean either that the first transistor has a source region electrically connected to a drain region of the second transistor, or that the first transistor has a drain region electrically connected to a source region of the second transistor.

Further, throughout the specification, the phrase “in a plan view” means viewing an object portion from above (i.e., from the top), and the phrase “in a schematic cross-sectional view” means viewing a cross-section of which the object is vertically cut from the side. Hence, the expression “in a plan view” used herein may mean that an object is viewed in a third direction DR3 from the top. The phrase “in a schematic cross-sectional view” means viewing a cross-section in a first direction DR1 or a second direction DR2 of which the object is vertically cut from the side.

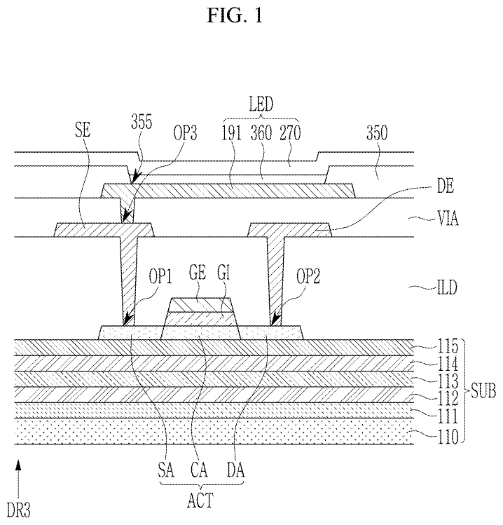

Hereinafter, a display device according to an embodiment will be described in detail with reference to the drawings. FIG. 1 schematically illustrates a schematic cross-sectional view of a display device according to an embodiment. Referring to FIG. 1, the display device according to the embodiment may include a multi-layered substrate SUB and a semiconductor layer ACT that may include an oxide semiconductor. The display device according to the embodiment includes a structure within a substrate SUB that improves light reliability of a transistor including an oxide semiconductor.

Referring to FIG. 1, the substrate SUB according to the embodiment may include a base layer 110, a first organic layer 111, a first barrier layer 112, a second organic layer 113, a second barrier layer 114, and a shielding layer 115. The substrate SUB may be a rigid substrate or a flexible substrate capable of bending, folding, rolling, or the like.

The base layer 110 may be made of glass. However, this is merely an example, and the base layer 110 may be omitted according to an embodiment. The first organic layer 111 and the second organic layer 113 each may include polyimide. The first barrier layer 112 and the second barrier layer 114 each may include an inorganic material. The first barrier layer 112 and the second barrier layer 114 each may include at least one of a silicon oxide (SiOₓ), a silicon nitride (SiNₓ), a silicon oxynitride (SiOₓN_{y}), amorphous silicon (Si), or a combination thereof.

The shielding layer 115 may include benzocyclobutene. For example, the shielding layer may include a compound represented by Chemical Formula 1 below.

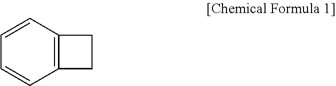

As described later, in the substrate SUB according to the embodiment, the shielding layer 115 may be positioned on the first organic layer 111 and the second organic layer 113. The shielding layer 115 may include benzocyclobutene represented by Chemical Formula 1, and the shielding layer 115 may have a lower dielectric constant and lower polarity in a molecular structure compared to the polyimide included in the first organic layer 111 and the second organic layer 113, and thus it may shield an electric charge. Additional effects will be described later separately.

A thickness of the shielding layer 115 may be about 0.5 μm to about 10 μm. In case that the thickness of the shielding layer 115 is less than about 0.5 μm, a sufficient shielding effect cannot be obtained, and in case that the thickness of the shielding layer 115 is greater than about 10 μm, a thickness of an organic film becomes excessively thick, and thus wrinkles may occur during a formation process.

A semiconductor layer ACT may be disposed on the substrate SUB. The semiconductor layer ACT may include polycrystalline silicon or an oxide semiconductor. The semiconductor layer ACT may include a channel area CA overlapping and facing a gate electrode GE in a thickness direction DR3. The semiconductor layer ACT also may include a source area SA and a drain area DA positioned or disposed at opposite sides of the channel area CA.

As illustrated in FIG. 1, the semiconductor layer ACT may be disposed directly on the shielding layer 115 of the substrate SUB, such that the shielding layer 115 may directly contact the semiconductor layer ACT. Hence, the shielding layer 115 is disposed between the semiconductor layer ACT and any one of the first organic layer 111, the first barrier layer 112, the second organic layer 113, and the second barrier layer 114, such that the shielding layer 115 is disposed closest to the semiconductor layer ACT relative to other layers of the substrate SUB. A gate insulating layer GI1 may be disposed on the semiconductor layer ACT. The gate insulating layer GI may include a silicon oxide (SiOₓ), a silicon nitride (SiNₓ), or a silicon oxynitride (SiOₓN_{y}), and may have a single or multi-layered structure including the same.

The gate insulating layer GI may be positioned to overlap and face the channel area CA of the semiconductor layer ACT in a thickness direction DR3. A gate conductive layer including a gate electrode GE may be positioned on the gate insulating layer GI. The gate conductive layer may include molybdenum (Mo), aluminum (Al), copper (Cu), titanium (Ti), and/or a metal oxide, or a combination thereof, and may have a single or multi-layered structure including the same.

The gate electrode GE may be formed in a same process as the gate insulating layer GI to have a same planar shape. The gate electrode GE may be positioned to overlap and face the semiconductor layer ACT in a thickness direction DR3 that is perpendicular to a surface of the substrate SUB.

An interlayer insulating layer ILD may be disposed on the semiconductor layer ACT and the gate electrode GE. The interlayer insulating layer ILD may include a silicon oxide (SiOₓ), a silicon nitride (SiNₓ), or a silicon oxynitride (SiOₓN_{y}), or a combination thereof, and may have a single or multi-layered structure including the same. In case that the interlayer insulating layer ILD has a multi-layered structure including a silicon nitride and a silicon oxide, a layer including a silicon nitride may be disposed closer to the substrate SUB than a layer including a silicon oxide.

The interlayer insulating layer ILD may include a first opening OP1 overlapping and facing the source area SA of the semiconductor layer ACT and a second opening OP2 overlapping and facing a drain area DA in a thickness direction DR3.

A data conductive layer including the source electrode SE and the drain electrode DE may be positioned on the interlayer insulating layer ILD. The data conductive layer may include aluminum (Al), silver (Ag), magnesium (Mg), gold (Au), nickel (Ni), chromium (Cr), calcium (Ca), molybdenum (Mo), titanium (Ti), tungsten (W), and/or copper (Cu), and/or a metal oxide thereof, or a combination thereof, and may have a single or multi-layered structure including the same.

The source electrode SE may contact the source area SA of the semiconductor layer ACT through the first opening OP1. The drain electrode DE may contact the drain area DA of the semiconductor layer ACT in the second opening OP2.

An insulating layer VIA may be positioned on the data conductive layer. The insulating layer VIA may include an organic insulating material such as a general purpose polymer, e.g., poly(methyl methacrylate) (PMMA) or polystyrene (PS), a polymer derivative having a phenolic group, an acrylic polymer, an imide polymer, a polyimide, a siloxane polymer, etc., or a combination thereof.

The insulating layer VIA may have a third opening OP3 overlapping and facing the source electrode SE in a thickness direction DR3. A first electrode 191 may be positioned on the insulating layer VIA. A partition wall or bank 350 may be positioned on the insulating layer VIA and the first electrode 191. The partition bank 350 may have an opening 355 overlapping and facing the first electrode 191 in a thickness direction DR3. An emission layer 360 may be disposed in the opening 355. A second electrode 270 may be disposed on the partition bank 350 and the emission layer 360. The first electrode 191, the emission layer 360, and the second electrode 270 may constitute a light emitting diode LED.

An effect of the display device according to the embodiment will be described below. The shielding layer 115 may be disposed at a lower portion of the semiconductor layer ACT to improve light reliability of a transistor including an oxide semiconductor.

The first organic layer 111 and the second organic layer 113 of the display device each may include polyimide. This polyimide may have a structure shown in Chemical Formula 2 below. As shown in the following Chemical Formula 2, a molecular structural formula of polyimide may be divided into a donor region and an acceptor region, and this structure facilitates movement of electrons by UV irradiation.

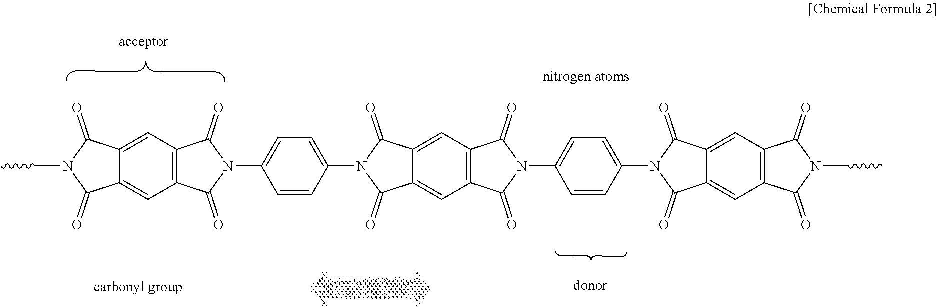

For example, the polyimide may have an intramolecular charge transfer complex (CTC) structure as shown in Chemical Formula 3 below.

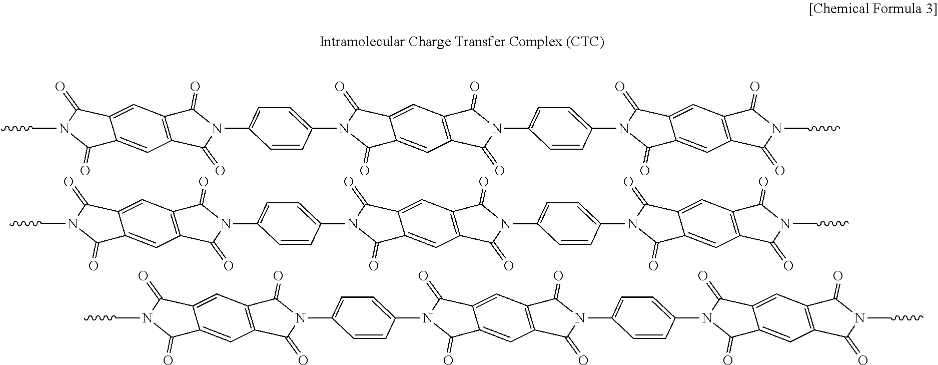

During use of the display device, electron movement occurs in the polyimide by irradiation of internal or external light, and such movement of electrons affects reliability of the semiconductor layer. An operation of the semiconductor layer is affected by charges stored in the first organic layer 111 and the second organic layer 113 disposed at the lower portion of the semiconductor layer. In particular, in case that the semiconductor layer may include an oxide semiconductor, a reliability problem due to charge movement of polyimide may significantly appear.

However, the display device according to the embodiment solves this problem by disposing the shielding layer 115 between the semiconductor layer and the polyimide layer. The shielding layer 115 may include benzocyclobutene. For example, the shielding layer may include a compound made of Chemical Formula 1 below.

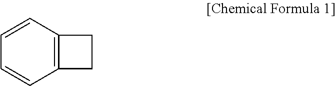

Such benzocyclobutene does not include an intramolecular charge transfer complex (CTC) structure like polyimide. The benzocyclobutene has a lower polarity than that of a polyimide molecular structure, and also has a dielectric constant of 2.85, which is about 35% lower than that of polyimide, which is 4.4. Accordingly, the shielding layer 115 including benzocyclobutene may have a shielding function.

However, a high heat resistance is needed during a manufacturing process of display devices. A high temperature is used in a manufacturing process of display devices, and thus even in case that a charge shielding function is excellent, it may be difficult to apply the high temperature as part of the manufacturing process in case that the heat resistance is poor.

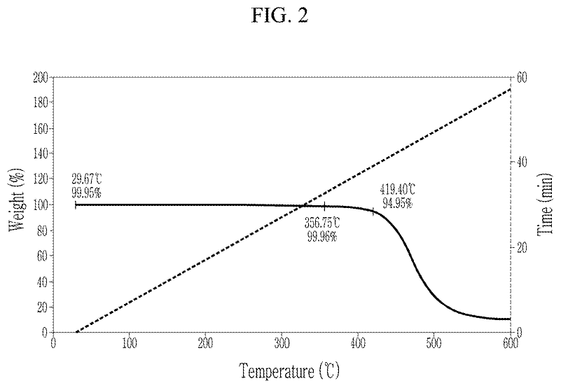

FIG. 2 illustrates a weight percentage “%” relative to a temperature of benzocyclobutene. Referring to FIG. 2, even in case that a temperature rises to about 350° C., it was confirmed that weight change is less than 1 wt %. Even in case that the temperature rises to about 400° C., it was confirmed that the weight change was less than 5 wt % and it had high heat resistance.

FIG. 1 illustrates an embodiment in which the shielding layer 115 may be disposed on top of the substrate SUB. However, a position of the shielding layer 115 may be different according to an embodiment.

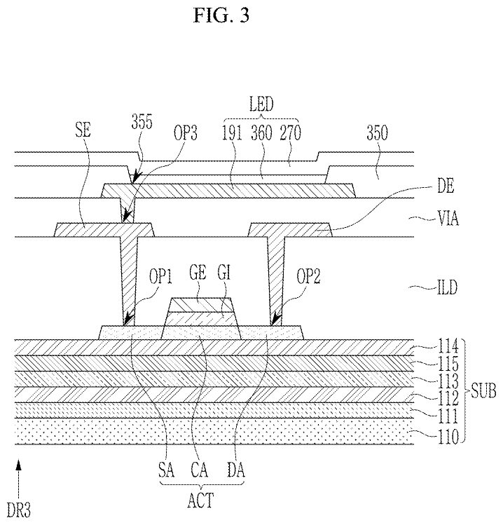

FIG. 3 illustrates a display device according to an embodiment. Referring to FIG. 3, the shielding layer 115 may be disposed between the second organic layer 113 and the second barrier layer 114, and the second barrier layer 114 may directly contact the semiconductor layer ACT. The embodiment of FIG. 3 is the same as the embodiment of FIG. 1 except that the shielding layer 115 is disposed between the second organic layer 113 and the second barrier layer 114, such that the second barrier layer 114 is disposed between the semiconductor layer ACT and any one of the first organic layer 111, the first barrier layer 112, the second organic layer 113, and the shielding layer 115. A detailed description of the same constituent elements will be omitted.

As illustrated in FIG. 1, the shielding effect may be best in case that the shielding layer 115 is disposed on top of the substrate SUB. However, in case that the shielding layer 115 is disposed on top of the substrate SUB, moisture or the like may permeate into a device. Accordingly, as illustrated in FIG. 3, the shielding layer 115 may be disposed between the second organic layer 113 and the second barrier layer 114. In the case of the embodiment of FIG. 3, the electromagnetic shielding performance may be lower than that of FIG. 1, but the second barrier layer 114, which is an inorganic film, is positioned on top of the substrate SUB, and thus moisture penetration into the device may be prevented.

Hereinafter, a display device in which the substrate SUB includes the shielding layer 115 will be described in detail with reference to drawings. However, the following description is an example, and the disclosure is not limited thereto. In the display device according to the embodiment, transistors each may include an oxide semiconductor and/or a polycrystalline semiconductor, described in further detail below.

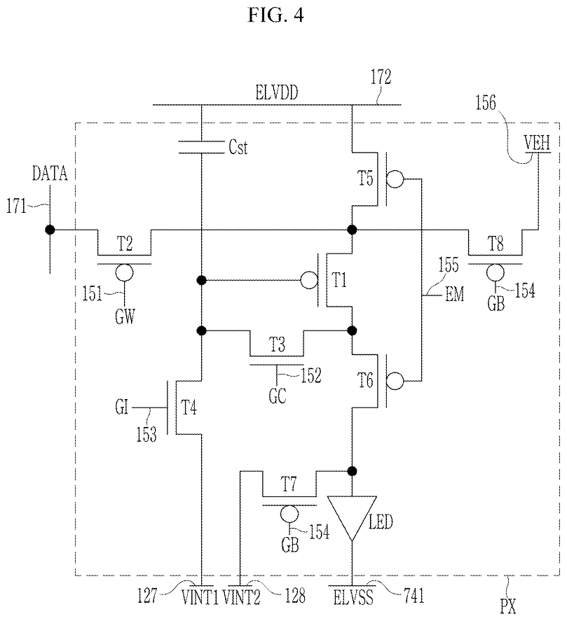

FIG. 4 illustrates a circuit diagram of an equivalent circuit of a pixel of a display device according to an embodiment.

As illustrated in FIG. 4, according to the embodiment, a pixel PX of the display device may include transistors T1, T2, T3, T4, T5, T6, T7, and T8, a holding capacitor Cst, and a light emitting diode LED electrically connected to various signal lines.

Signal lines 127, 128, 151, 152, 153, 154, 155, 156, 171, 172, and 741 may be electrically connected to a pixel PX. The signal lines may include a first initialization voltage line 127, a second initialization voltage line 128, a first scan line 151, a second scan line 152, an initialization control line 153, a bypass control line 154, an emission control line 155, a reference voltage line 156, a data line 171, a driving voltage line 172, and a common voltage line 741.

The first scan line 151 may be electrically connected to a gate driver (not illustrated) to transfer a first scan signal GW to the second transistor T2. A voltage having a polarity that is opposite to that of the voltage applied to the first scan line 151 may be applied to the second scan line 152 at a same timing as a signal of the first scan line 151. For example, in case that a high voltage is applied to the first scan line 151, a low voltage may be applied to the second scan line 152. The second scan line 152 may transmit a second scan signal GC to the third transistor T3.

The initialization control line 153 may transmit an initialization control signal GI to the fourth transistor T4. The bypass control line 154 may transfer a bypass signal GB to the seventh transistor T7 and the eighth transistor T8. The bypass control line 154 may be formed by a next-stage first scan line 151. The emission control line 155 may transmit an emission control signal EM to the fifth transistor T5 and the sixth transistor T6.

The data line 171 may be a wire for transmitting a data voltage DATA generated by a data driver (not illustrated), and luminance of the organic light emitting diode LED that emits light may be changed based on (in response to) the data voltage DATA applied to the pixel PX.

The driving voltage line 172 may apply a driving voltage ELVDD, and the reference voltage line 156 may apply a reference voltage VEH. The first initialization voltage line 127 may transfer a first initialization voltage VINT1, and the second initialization voltage line 128 may transfer the second initialization voltage VINT2. The common voltage line 741 may apply a common voltage ELVSS to a cathode of the light emitting diode LED. In the embodiment, voltages applied to the driving voltage line 172, the reference voltage line 156, the first and second initialization voltage lines 127 and 128, and the common voltage line 741 may be constant voltages, respectively.

Hereinafter, a structure and connection relationship of the transistors will be described in detail.

The driving transistor T1 may have a p-type transistor characteristic, and may include a polycrystalline semiconductor. The driving transistor T1 may receive a data voltage DATA based on a switching operation of the second transistor T2, and may supply a driving current to an anode of the light emitting diode LED. A brightness of the light emitting diode LED may be adjusted based on a magnitude of the driving current output to the anode electrode of the light emitting diode LED, and thus the brightness of the light emitting diode LED may be adjusted based on the data voltage DATA applied to the pixel PX. For this purpose, a first region of the driving transistor T1 may be electrically connected to the driving voltage line 172 via the fifth transistor T5 by being positioned to receive the driving voltage ELVDD. The first region of the driving transistor T1 also may be electrically connected to a second region of the second transistor T2 to receive the data voltage DATA. A second region of the driving transistor T1 may be positioned to output a current toward the light emitting diode LED, and may be electrically connected to an anode of the light emitting diode LED via the sixth transistor T6. The second region of the driving transistor T1 may transfer the data voltage DATA applied to the first region to the third transistor T3. A gate electrode of the driving transistor T1 may be electrically connected to a first electrode (hereinafter, referred to as a “second storage electrode”) of the storage capacitor Cst. Accordingly, the voltage of the gate electrode of the driving transistor T1 may change based on a voltage stored in the storage capacitor Cst, and a driving current that is output by the driving transistor T1 may change accordingly. The storage capacitor Cst may be configured to maintain a voltage of the gate electrode of the driving transistor T1 to be constant during a frame.

The second transistor T2 may have a p-type transistor characteristic, and may include a polycrystalline semiconductor. The second transistor T2 may be a transistor that receives the data voltage DATA into the pixel PX. A gate electrode of the second transistor T2 may be electrically connected to the first scan line 151. A first region of the second transistor T2 may be electrically connected to the data line 171. The second region of the second transistor T2 may be electrically connected to the first region of the driving transistor T1. In case that the second transistor T2 is activated by a low voltage of the first scan signal GW transferred through the first scan line 151, the data voltage DATA transferred through the data line 171 may be transferred to the first region of the driving transistor T1.

The third transistor T3 may have an n-type transistor characteristic, and may include an oxide semiconductor. The third transistor T3 may electrically connect the second region of the driving transistor T1 and the gate electrode of the driving transistor T1. As a result, the third transistor T3 may cause a compensation voltage obtained by changing the data voltage DATA through the driving transistor T1 to be transferred to the second storage electrode of the storage capacitor Cst. A gate electrode of the third transistor T3 may be electrically connected to the second scan line 152, and a first region of the third transistor T3 may be electrically connected to the second region of the driving transistor T1. The second region of the third transistor T3 may be electrically connected to the second storage electrode of the storage capacitor Cst and the gate electrode of the driving transistor T1. The third transistor T3 may be activated by a high voltage among the second scan signals GC received through the second scan line 152, to electrically connect the gate electrode of the driving transistor T1 and the second region of the driving transistor T1, and the voltage applied to the gate electrode of the driving transistor T1 may be transferred to the second storage electrode of the storage capacitor Cst, causing storage of the voltage in the storage capacitor Cst.

The four transistor T4 may have an n-type transistor characteristic, and may include an oxide semiconductor. The fourth transistor T4 may be configured to initialize the gate electrode of the driving transistor T1 and the second storage electrode of the storage capacitor Cst. The gate electrode of the fourth transistor T4 may be electrically connected to the initialization control line 153, and a first region of the fourth transistor T4 may be electrically connected to the first initialization voltage line 127. A second region of the fourth transistor T4 may be electrically connected to the second storage electrode of the storage capacitor Cst and the gate electrode of the driving transistor T1 via the second region of the third transistor T3. The fourth transistor T4 may be activated by a high voltage of the initialization control signal GI transferred through the initialization control line 153, and the first initialization voltage VINT1 may be transferred to the gate electrode of the driving transistor T1 and the second storage electrode of the storage capacitor Cst. Accordingly, a voltage of the gate electrode of the driving transistor T1 and the storage capacitor Cst may be initialized.

The fifth transistor T5 may have a p-type transistor characteristic, and may include a polycrystalline semiconductor. The fifth transistor T5 may be configured to transfer the driving voltage ELVDD to the driving transistor T1. A gate electrode of the fifth transistor T5 may be electrically connected to the emission control line 155, a first region of the fifth transistor T5 may be electrically connected to the driving voltage line 172, and a second region of the fifth transistor T5 may be electrically connected to the first region of the driving transistor T1.

The sixth transistor T6 may have a p-type transistor characteristic, and may include a polycrystalline semiconductor. The sixth transistor T6 may be configured to transfer a driving current output from the driving transistor T1 to the light emitting diode. The gate electrode of the sixth transistor T6 may be electrically connected to the emission control line 155, a first region of the sixth transistor T6 may be electrically connected to the second region of the driving transistor T1, and a second region of the sixth transistor T6 may be electrically connected to the anode of the light emitting diode LED.

The seventh transistor T7 may have a p-type transistor characteristic, and may include a polycrystalline semiconductor. The seventh transistor T7 may be configured to initialize the anode of the light emitting diode LED. A gate electrode of the seventh transistor T7 may be electrically connected to the bypass control line 154, a first region of the seventh transistor T7 may be electrically connected to the anode of the light emitting diode LED, and a second region of the seventh transistor T7 may be electrically connected to the second initialization voltage line 128. In case that the seventh transistor T7 is activated by a low voltage of the bypass signal GB, the second initialization voltage VINT2 may be applied to the anode of the light emitting diode LED to be initialized. The eighth transistor T8 may have a p-type transistor characteristic, and may include a polycrystalline semiconductor. A gate electrode of the eighth transistor T8 may be electrically connected to the bypass control line 154, a first region of the eighth transistor T8 may be electrically connected to the reference voltage line 156, and a second region of the eighth transistor T8 may be electrically connected to the first region of the driving transistor T1. In case that the eighth transistor T8 is activated by the low voltage of the bypass signal GB, the reference voltage VEH may be applied to the first region of the driving transistor T1.

It has been described above that a pixel may include transistors T1 to T8 and a storage capacitor Cst, but the embodiment is not limited thereto, and a number of transistors, a number of capacitors, and their connection relationships may be changed.

In an embodiment, the driving transistor T1 may include a polycrystalline semiconductor. The third transistor T3 and the fourth transistor T4 each may include an oxide semiconductor. The second transistor T2, the fifth transistor T5, the sixth transistor T6, the seventh transistor T7, and the eighth transistor T8 may include a polycrystalline semiconductor. However, the embodiment is not limited thereto, and at least one of the second transistor T2, the fifth transistor T5, the sixth transistor T6, the seventh transistor T7, or the eighth transistor T8 may include an oxide semiconductor. In the embodiment, more stable driving may be achieved and reliability may be improved by including in the third transistor T3 and the fourth transistor T4 a semiconductor material that is different from that of the driving transistor T1.

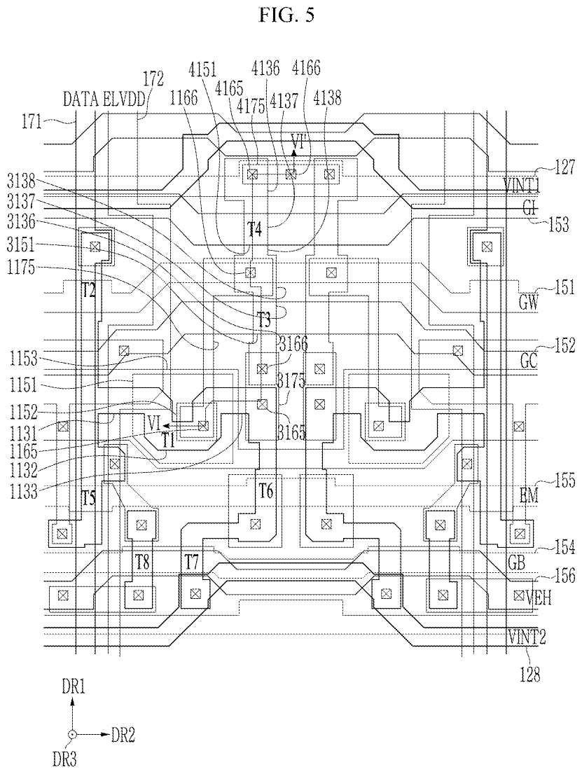

Hereinafter, structures of the driving transistor T1, the third transistor T3, and the fourth transistor T4 in plan views and schematic cross-sectional views will be further described with reference to FIG. 5 to FIG. 12.

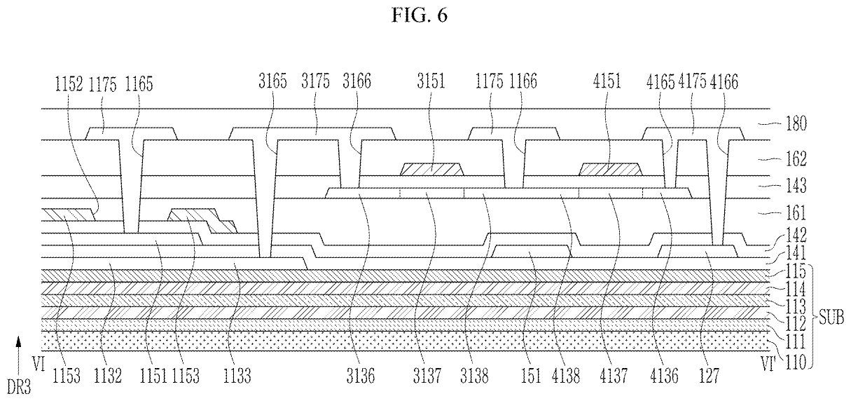

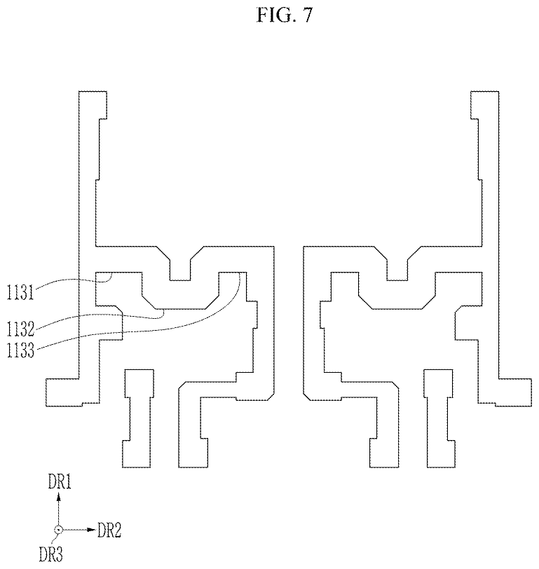

FIG. 5 illustrates a top plan view of a display device according to an embodiment, FIG. 6 illustrates a schematic cross-sectional view taken along a line VI-VI′ of FIG. 5, and FIG. 7 to FIG. 12 illustrate top plan views sequentially showing a display device according to a manufacturing process according to an embodiment. FIG. 5 to FIG. 12 illustrate two adjacent pixels, and the two pixels may have shapes that may be symmetrical to each other. Hereinafter, a pixel positioned at a left side will be described.

As illustrated in FIG. 5 to FIG. 12, a polycrystalline semiconductor layer including the channel 1132 of the driving transistor T1, the first region 1131, and the second region 1133 may be disposed on the substrate SUB.

A description of the substrate SUB is the same as described above. For example, the substrate SUB may include a base layer 110, a first organic layer 111, a first barrier layer 112, a second organic layer 113, a second barrier layer 114, and a shielding layer 115. The shielding layer 115 may include benzocyclobutene. A thickness of the shielding layer 115 may be about 0.5 μm to about 10 μm. Specific configurations and effects are omitted as they are the same as described above. In FIG. 6, the substrate SUB is illustrated to have a same structure as that in FIG. 1 (the shielding layer may be disposed on top of the substrate), but the substrate SUB may have a same structure as that in the embodiment of FIG. 3 (the shielding layer may be disposed between the second organic layer and the second barrier layer).

FIG. 7 illustrates the polycrystalline semiconductor layer. The polycrystalline semiconductor layer may further include a channel, a first region, and a second region of each of not only the driving transistor T1 but also the second transistor T2, the fifth transistor T5, the sixth transistor T6, the seventh transistor T7, and the eighth transistor T8.

The channel 1132 of the driving transistor T1 may have a bent shape in a plan view. However, the shape of the channel 1132 of the driving transistor T1 is not limited thereto, and may be variously changed. For example, the channel 1132 of the driving transistor T1 may be bent in a different shape, or may be formed in a bar-like shape. The first region 1131 and the second region 1133 of the driving transistor T1 may be positioned at opposite sides of the channel 1132 of the driving transistor T1. The first region 1131 of the driving transistor T1 may extend upward and downward in a plan view, a portion extending upward may be electrically connected to the second region of the second transistor T2, and a portion extending downward may be electrically connected to the second region of the fifth transistor T5. The second region 1133 of the driving transistor T1 may extend downward in a plan view to be electrically connected to the first region of the sixth transistor T6.

A first gate insulating layer 141 may be disposed on the polycrystalline semiconductor layer including the channel 1132, the first region 1131, and the second region 1133 of the driving transistor T1. The first gate insulating layer 141 may include a silicon nitride (SiNₓ), a silicon oxide (SiOₓ), or a silicon oxynitride (SiOₓN_{y}), or a combination thereof, and may have a single or multi-layered structure including the same.

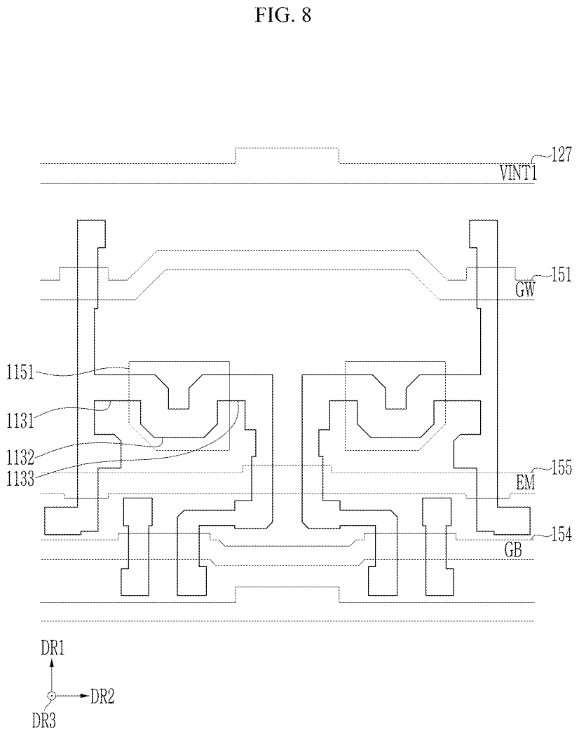

A first gate conductive layer including a gate electrode 1151 of the driving transistor T1 may be positioned on the first gate insulating layer 141. FIG. 8 illustrates a polycrystalline semiconductor layer and a first gate conductive layer together. The first gate conductive layer may include molybdenum (Mo), aluminum (Al), copper (Cu), and/or titanium (Ti), or a combination thereof, and may have a single or multi-layered structure having the same.

The gate electrode 1151 of the driving transistor T1 may overlap and face the channel 1132 of the driving transistor T1 in a thickness direction DR3. The channel 1132 of the driving transistor T1 may overlap and face the electrode channel 1151 of the driving transistor T1 in a thickness direction DR3.

The first gate conductive layer may further include a first initialization voltage line 127, a first scan line 151, an emission control line 155, and a bypass control line 154. The first initialization voltage line 127, the first scan line 151, the emission control line 155, and the bypass control line 154 may extend in a substantially horizontal direction DR2. The first initialization voltage line 127 may be electrically connected to the first region of the fourth transistor T4. The first scan line 151 may be electrically connected to the gate electrode of the second transistor T2. The gate electrode of the fifth transistor T5 and the gate electrode of the sixth transistor T6 may be electrically connected to the emission control line 155. The gate electrode of the seventh transistor T7 and the gate electrode of the eighth transistor T8 may be electrically connected to the bypass control line 154.

As described above, a first gate layer GATT of the pad portion PA may be disposed on the first gate conductive layer. Accordingly, the first gate layer GAT1 and the gate electrode 1151 of the driving transistor T1 may be disposed on a same layer. The first gate layer GAT1, the first initialization voltage line 127, the first scan line 151, the emission control line 155, and the bypass control line 154 may be disposed on a same layer.

After the first gate conductive layer including the gate electrode 1151 of the driving transistor T1 is formed, a doping process may be performed. The polycrystalline semiconductor layer that is covered by the first conductive layer may be doped, and a portion of the polycrystalline semiconductor layer that is not covered by the first conductive layer may be doped to have a same characteristic as that of a conductor. A doping process may be performed with a p-type dopant, and the driving transistor T1, the second transistor T2, the fifth transistor T5, the sixth transistor T6, the seventh transistor T7 including a polycrystalline semiconductor, and the eighth transistor T8 may have a p-type transistor characteristic.

A second gate insulating layer 142 may be disposed on the first gate insulating layer 141 and the first gate conductive layer including the gate electrode 1151 of the driving transistor T1. The second gate insulating layer 142 may include a silicon oxide (SiOₓ), a silicon nitride (SiNₓ), or a silicon oxynitride (SiOₓN_{y}), or a combination thereof, and may have a single or multi-layered structure including the same.

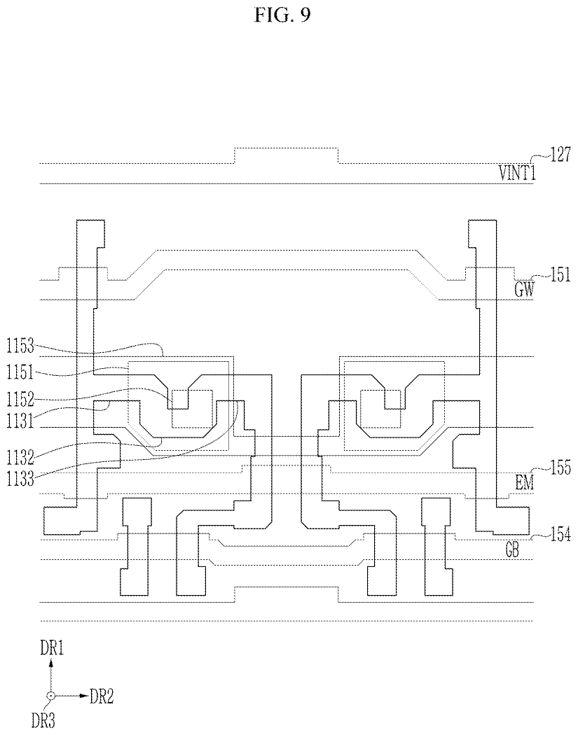

A second gate conductive layer including the first storage electrode 1153 of the storage capacitor Cst may be positioned on the second gate insulating layer 142. FIG. 9 illustrates the polycrystalline semiconductor layer, the first gate conductive layer, and the second gate conductive layer together. The second gate conductive layer may include molybdenum (Mo), aluminum (Al), copper (Cu) silver (Ag), chromium (Cr), tantalum (Ta), titanium (Ti), and the like, or a combination thereof, and may have a single or multi-layered structure including the same.

The first storage electrode 1153 overlaps the gate electrode 1151 of the driving transistor T1 in a thickness direction DR3 to constitute the storage capacitor Cst. An opening 1152 may be formed in the first storage electrode 1153 of the storage capacitor Cst. The opening 1152 of the first storage electrode 1153 of the storage capacitor Cst may overlap and face the gate electrode 1151 of the driving transistor T1 in a thickness direction DR3.

As described above, a second gate layer GAT2 of the pad portion PA may be disposed on the second gate conductive layer. Accordingly, in case that the pad portion PA includes the first gate layer GAT2 instead of the first gate layer GAT1, the second gate layer GAT2 and the first storage electrode 1153 of the storage capacitor Cst may be disposed on a same layer.

A first interlayer insulating layer 161 may be disposed on the second gate conductive layer including the first storage electrode 1153 of the storage capacitor Cst. The first interlayer insulating layer 161 may include a silicon oxide (SiOₓ), a silicon nitride (SiNₓ), or a silicon oxynitride (SiOₓN_{y}), or a combination thereof, and may have a single or multi-layered structure including the same.

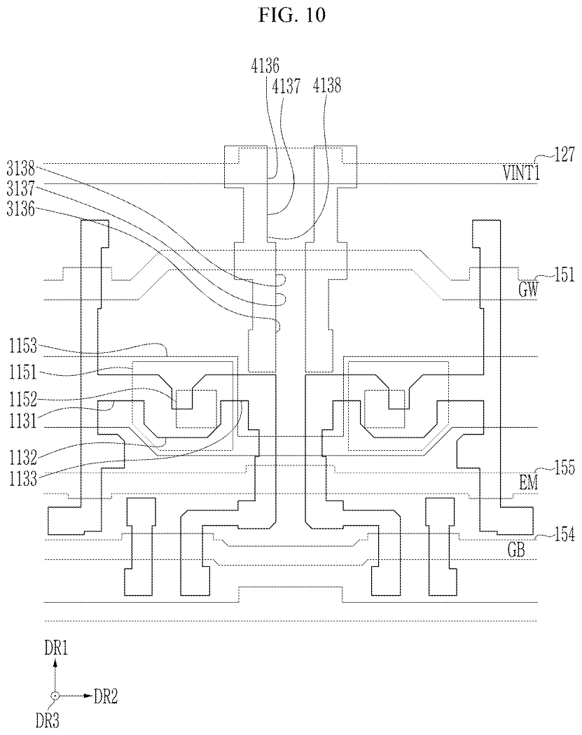

An oxide semiconductor layer including the channel 3137, the first area 3136, and the second area 3138 of the third transistor T3, and the channel 4137, the first area 4136, and the second area 4138 of the fourth transistor T4, may be positioned on the first interlayer insulating layer 161. FIG. 10 illustrates the polycrystalline semiconductor layer, the first gate conductive layer, the second gate conductive layer, and an oxide semiconductor layer together. The oxide semiconductor layer may include an indium-gallium-zinc oxide (IGZO) among In—Ga—Zn-based oxides.

The channel 3137, the first region 3136, and the second region 3138 of the third transistor T3, and the channel 4137, the first region 4136, and the second region 4138 of the fourth transistor T4, may be electrically connected to each other and may be integral with each other. The first region 3136 and the second region 3138 of the third transistor T3 may be positioned at opposite sides of the channel 3137 of the third transistor T3. The first region 4136 and the second region 4138 of the fourth transistor T4 may be positioned at opposite sides of the channel 4137 of the fourth transistor T4. The second region 3138 of the third transistor T3 may be electrically connected to the second region 4138 of the fourth transistor T4.

A third gate insulating layer 143 may be positioned on the oxide semiconductor layer including the channel 3137, the first area 3136, and the second area 3138 of the third transistor T3, and the channel 4137, the first area 4136, and the second area 4138 of the fourth transistor T4. The third gate insulating layer 143 may include a silicon oxide (SiOₓ), a silicon nitride (SiNₓ), or a silicon oxynitride (SiOₓN_{y}), or a combination thereof, and may have a single or multi-layered structure including the same.

The third gate insulating layer 143 may be positioned on entire surfaces of the oxide semiconductor layer and the first interlayer insulating layer 161. The third gate insulating layer 143 may cover upper surfaces and side surfaces of the channel 3137, the first region 3136, and the second region 3138 of the third transistor T3, and the channel 4137, the first region 4136, and the second region 4138 of the fourth transistor T4. However, the embodiment is not limited thereto, and the third gate insulating layer 143 may not be positioned on entire surfaces of the oxide semiconductor layer and the first interlayer insulating layer 161. For example, the third gate insulating layer 143 may overlap and face the channel 3137 of the third transistor T3 in a thickness direction DR3, and may not overlap the first region 3136 and the second region 3138. The third gate insulating layer 143 may overlap and face the channel 4137 of the fourth transistor T4 in a thickness direction DR3, and may not overlap the first region 4136 and the second region 4138.

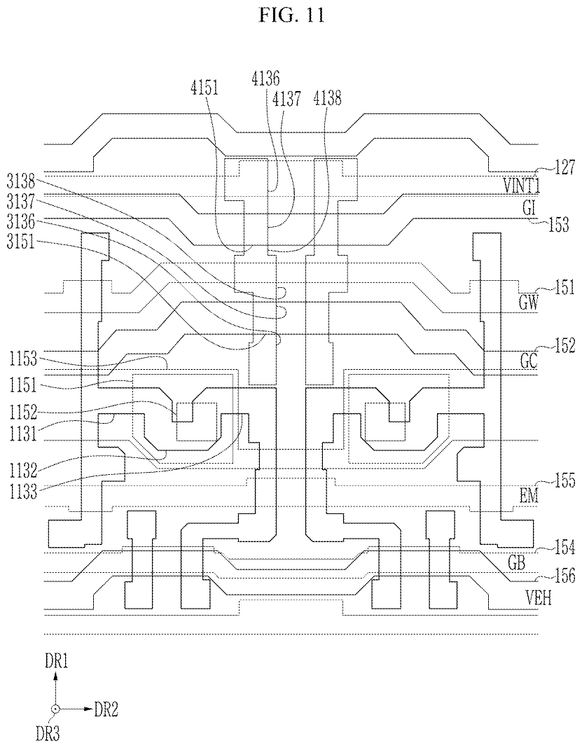

A third gate conductive layer including the gate electrode 3151 of the third transistor T3 and the gate electrode 4151 of the fourth transistor T4 may be positioned on the third gate insulating layer 143. FIG. 11 illustrates the polycrystalline semiconductor layer, the first gate conductive layer, the second gate conductive layer, the oxide semiconductor layer, and the third gate conductive layer together. The third gate conductive layer may include molybdenum (Mo), aluminum (Al), copper (Cu), and/or titanium (Ti), or a combination thereof, and may have a single or multi-layered structure including the same. For example, the third gate conductive layer may include a lower layer including titanium and an upper layer including molybdenum.

The gate electrode 3151 of the third transistor T3 may overlap and face the channel 3137 of the third transistor T3 in a thickness direction DR3. The gate electrode 4151 of the fourth transistor T4 may overlap and face the channel 4137 of the fourth transistor T4 in a thickness direction DR3.

The third gate conductive layer may further include an initialization control line 153, a second scan line 152, and a reference voltage line 156. The initialization control line 153, the second scan line 152, and the reference voltage line 156 may extend substantially in a horizontal direction DR2. The initialization control line 153 may be electrically connected to the gate electrode 4151 of the fourth transistor T4. The second scan line 152 may be electrically connected to the gate electrode 3151 of the third transistor T3. The reference voltage line 156 may be electrically connected to the first region of the eighth transistor T8.

As described above, a third gate layer GAT3 of the pad portion PA may be disposed on the third gate conductive layer. Accordingly, the third gate layer GAT3, the gate electrode 3151 of the third transistor T3, and the gate electrode 4151 of the fourth transistor T4 may be disposed on a same layer. The third gate layer GAT3 and the initialization control line 153, the second scan line 152, and the reference voltage line 156 may be disposed on a same layer.

After the third gate conductive layer including the gate electrode 3151 of the third transistor T3 and the gate electrode 4151 of the fourth transistor T4 is formed, a doping process may be performed. A portion of the oxide semiconductor layer covered by the third gate conductive layer may not be doped, and a portion of the oxide semiconductor layer not covered by the third gate conductive layer may be doped to have a same characteristic as the conductor. The channel 3137 of the third transistor T3 may be positioned under the gate electrode 3151 to overlap and face the gate electrode 3151 in a thickness direction DR3. The first region 3136 and the second region 3138 of the third transistor T3 may not overlap the gate electrode 3151. The channel 4137 of the fourth transistor T4 may be positioned under the gate electrode 4151 to overlap and face the gate electrode 4151 in a thickness direction DR3. The first region 4136 and the second region 4138 of the fourth transistor T4 may not overlap the gate electrode 4151. The doping process of the oxide semiconductor layer may be performed with an N-type dopant, and the third transistor T3 and the fourth transistor T4 including the oxide semiconductor layer may have an N-type transistor characteristic.

A second interlayer insulating layer 162 may be positioned on the third gate conductive layer including the gate electrode 3151 of the third transistor T3 and the gate electrode 4151 of the fourth transistor T4. The second interlayer insulating layer 162 may include a silicon nitride (SiNₓ), a silicon oxide (SiOₓ), or a silicon oxynitride (SiOₓN_{y}), or a combination thereof, and may have a single or multi-layered structure including the same. The second interlayer insulating layer 162 may include a first opening 1165, a second opening 1166, a third opening 3165, a fourth opening 3166, a fifth opening 4165, and a sixth opening 4166.

The first opening 1165 may overlap and face at least a portion of the gate electrode 1151 of the driving transistor T1 in a thickness direction DR3. The first opening 1165 may be further formed on the third gate insulating layer 143, the first interlayer insulating layer 161, and the second gate insulating layer 142. The first opening 1165 may overlap and face the opening 1152 of the first storage electrode 1153 in a thickness direction DR3. The first opening 1165 may be positioned inside the opening 1152 of the first storage electrode 1153. The second opening 1166 may overlap and face at least a portion of the second region 3138 of the third transistor T3 in a thickness direction DR3. The second opening 1166 may be further formed in the third gate insulating layer 143.

The third opening 3165 may overlap and face at least a portion of the second region 1133 of the driving transistor T1 in a thickness direction DR3. The third opening 3165 may be further formed in the third gate insulating layer 143, the first interlayer insulating layer 161, the second gate insulating layer 142, and the first gate insulating layer 141. The fourth opening 3166 may overlap and face at least a portion of the first region 3136 of the third transistor T3 in a thickness direction DR3. The fourth opening 3166 may be further formed in the third gate insulating layer 143.

The fifth opening 4165 may overlap and face at least a portion of the first region 4136 of the fourth transistor T4 in a thickness direction DR3. The fifth opening 4165 may be further formed in the third gate insulating layer 143. The sixth opening 4166 may overlap and face at least a portion of the first initialization voltage line 127 in a thickness direction DR3. The sixth opening 4166 may be further formed on the third gate insulating layer 143, the first interlayer insulating layer 161, and the second gate insulating layer 142.

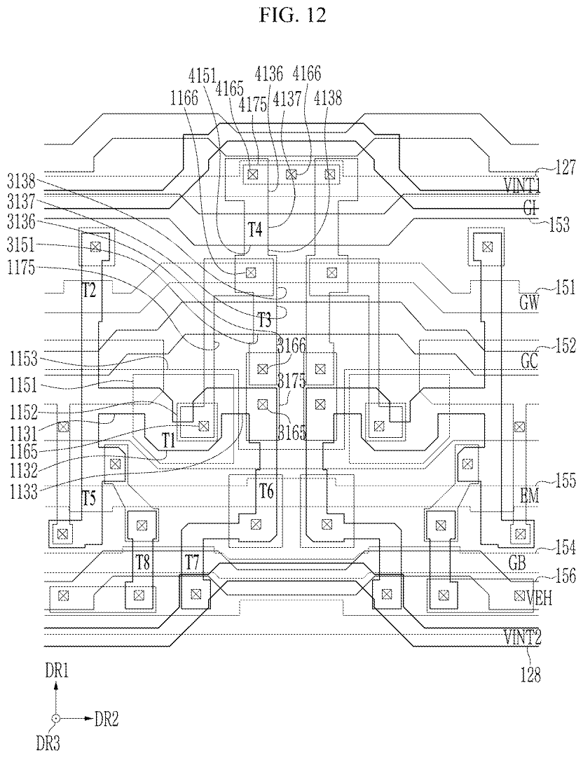

A first data conductive layer including a first connection electrode 1175, a second connection electrode 3175, and a third connection electrode 4175 may be positioned on the second interlayer insulating layer 162. FIG. 12 illustrates the polycrystalline semiconductor layer, the first gate conductive layer, the second gate conductive layer, the oxide semiconductor layer, the third gate conductive layer, and the first data conductive layer together. The first data conductive layer may include aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), tantalum (Ta), titanium (Ti), tungsten (W), copper (Cu), and/or the like, or a combination thereof, and may have a single layered structure or a multi-layered structure including the material. For example, the first data conductive layer may have a triple-layer structure of a lower film containing a refractory metal such as molybdenum, chromium, tantalum, or titanium, or an alloy thereof, an intermediate film containing an aluminum-based metal, a silver-based metal, or a copper-based metal having low resistivity, and an upper film containing a refractory metal such as molybdenum, chromium, tantalum, or titanium.

The first connection electrode 1175 may overlap and face the gate electrode 1151 of the driving transistor T1 in a thickness direction DR3. The first connection electrode 1175 may be electrically connected to the gate electrode 1151 of the driving transistor T1 through the first opening 1165 and the opening 1152 of the first storage electrode 1153. The first connection electrode 1175 may overlap and face the second region 3138 of the third transistor T3 in a thickness direction DR3. The first connection electrode 1175 may be electrically connected to the second region 3138 of the third transistor T3. Accordingly, the gate electrode 1151 of the driving transistor T1 and the second region 3138 of the third transistor T3 may be electrically connected by the first connection electrode 1175.

The second connection electrode 3175 may overlap and face the second region 1133 of the driving transistor T1 in a thickness direction DR3. The second connection electrode 3175 may be electrically connected to the second region 1133 of the driving transistor T1 through the third opening 3165. The second connection electrode 3175 may overlap and face the first region 3136 of the third transistor T3 in a thickness direction DR3. The second connection electrode 3175 may be electrically connected to the first region 3136 of the third transistor T3 through the fourth opening 3166. Accordingly, the second region 1133 of the driving transistor T1 and the first region 3136 of the third transistor T3 may be electrically connected by the third connection electrode 3175.

The third connection electrode 4175 may overlap and face the first region 4136 of the fourth transistor T4 in a thickness direction DR3. The third connection electrode 4175 may be electrically connected to the first region 4136 of the fourth transistor T4 through the fifth opening 4165. The third connection electrode 4175 may overlap and face the first initialization voltage line 127 in a thickness direction DR3. The third connection electrode 4175 may be electrically connected to the first initialization voltage line 127 through the sixth opening 4166. Accordingly, the first region 4136 of the fourth transistor T4 and the first initialization voltage line 127 may be electrically connected by the third connection electrode 4175.

The first data conductive layer may further include a second initialization voltage line 128. The second initialization voltage line 128 may extend substantially in the horizontal direction DR2. The second initialization voltage line 128 may be electrically connected to the second region of the seventh transistor T7.

As described above, a first data layer DAT1 of the pad portion PA may be disposed on the first data conductive layer. Accordingly, the first data layer DAT1, the first connection electrode 1175, the second connection electrode 3175, and the third connection electrode 4175 may be disposed on a same layer. The first data layer DAT1 and the second initialization voltage line 128 may be disposed on a same layer.

A third interlayer insulating layer 180 may be positioned on the first data conductive layer including the first connection electrode 1175, the second connection electrode 3175, and the third connection electrode 4175. The third interlayer insulating layer 180 may include an organic insulating material such as a general purpose polymer, e.g., poly(methyl methacrylate) (PMMA) or polystyrene (PS), a polymer derivative having a phenolic group, an acrylic polymer, an imide polymer, a polyimide, a siloxane polymer, etc., or a combination thereof.

A second data conductive layer including the data line 171 and the driving voltage line 172 may be disposed on the third interlayer insulating layer 180. The second data conductive layer may include aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), tantalum (Ta), titanium (Ti), tungsten (W), copper (Cu), and/or the like, or a combination thereof, and may have a single layered structure or a multi-layered structure including the material.

As shown in FIG. 5, the data line 171 and the driving voltage line 172 may extend in the vertical direction DR1. The data line 171 may be electrically connected to the second transistor T2. The data line 171 may be electrically connected to the first region of the second transistor T2. The driving voltage line 172 may be electrically connected to the fifth transistor T5. The driving voltage line 172 may be electrically connected to the first region of the fifth transistor T5. The driving voltage line 172 may be electrically connected to the storage capacitor Cst. The driving voltage line 172 may be electrically connected to the first storage electrode 1153 of the storage capacitor Cst. The first storage electrodes 1153 of the storage capacitors Cst of adjacent pixels may be electrically connected to each other, and may extend in a substantially horizontal direction DR2.

As described above, a second data layer DAT2 of the pad portion PA may be disposed on the second data conductive layer. Accordingly, the second data layer DAT2, the data line 171, and the driving voltage line 172 may be disposed on a same layer.

Although not illustrated, a passivation layer may be positioned on the second data conductive layer including the data line 171 and the driving voltage line 172, and an anode may be positioned on the passivation layer. The anode may be electrically connected to the sixth transistor T6, and may receive an output current of the driving transistor T1. A partition bank may be positioned on the anode. An opening may be formed in the partition bank, and the opening of the partition bank may overlap and face the anode in a thickness direction DR3. A light emitting diode layer may be disposed within the opening of the partition bank. A cathode may be positioned on the light emitting element layer and the partition bank. The anode, the light emitting diode layer, and the cathode may constitute a light emitting diode LED.

As described above, in the display device according to the embodiment, the substrate SUB may include the shielding layer 115 including benzocyclobutene. The shielding layer 115 may shield movement of charges generated in the polyimide layer of the substrate SUB, thereby improving reliability of the display device.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A display device comprising:
a substrate;
at least one transistor including a semiconductor layer disposed on the substrate; and
a light emitting device electrically connected to the at least one transistor, wherein
the substrate includes a first organic layer, a first barrier layer, a second organic layer, a second barrier layer, and a shielding layer,
the shielding layer includes a compound represented by Chemical Formula 1 below, and
the shielding layer is disposed between the second barrier layer and the semiconductor layer:

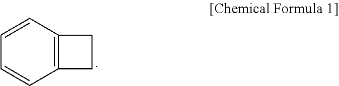

2. The display device of claim 1, wherein
a thickness of the shielding layer is about 0.5 μm to about 10 μm.

3. The display device of claim 1, wherein
the first organic layer and the second organic layer each include polyimide.

4. The display device of claim 1, wherein
the first barrier layer and the second barrier layer each include an inorganic material.

5. The display device of claim 1, wherein
the first organic layer, the first barrier layer, the second organic layer, the second barrier layer, and the shielding layer are sequentially stacked each other on the substrate, and
the shielding layer is disposed between the semiconductor layer and any one of the first organic layer, the first barrier layer, the second organic layer, and the second barrier layer.

6. The display device of claim 1, wherein
the semiconductor layer includes an oxide semiconductor.

7. The display device of claim 1, wherein
the semiconductor layer includes polycrystalline silicon.

8. The display device of claim 1, wherein
the at least one transistor further includes a plurality of transistors,
a first or more of the plurality of transistors include an oxide semiconductor, and
a second or more of the plurality of transistors include a polycrystalline semiconductor.

9. The display device of claim 1, wherein
the substrate further includes a base layer, and
the base layer includes glass.

10. The display device of claim 1, wherein
the shielding layer directly contacts the semiconductor layer.

11. A display device comprising:
a substrate;
at least one transistor including a semiconductor layer disposed on the substrate; and
a light emitting device electrically connected to the transistor,
wherein the substrate includes a first organic layer, a first barrier layer, a second organic layer, a shielding layer, and a second barrier layer,
the shielding layer includes a compound represented by Chemical Formula 1 below, and
the shielding layer is disposed between the second organic layer and the second barrier layer:

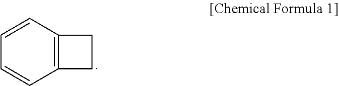

12. The display device of claim 11, wherein
a thickness of the shielding layer is about 0.5 μm to about 10 μm.

13. The display device of claim 11, wherein
the first organic layer and the second organic layer each include polyimide.

14. The display device of claim 11, wherein
the first barrier layer and the second barrier layer each include an inorganic material.

15. The display device of claim 11, wherein
the first organic layer, the first barrier layer, the second organic layer, the shielding layer, and the second barrier layer are sequentially stacked each other on the substrate, and
the second barrier layer is disposed between the semiconductor layer and any one of the first organic layer, the first barrier layer, the second organic layer, and the shielding layer.

16. The display device of claim 11, wherein
the semiconductor layer includes an oxide semiconductor.

17. The display device of claim 11, wherein
the semiconductor layer includes polycrystalline silicon.

18. The display device of claim 11, wherein
the at least one transistor further includes a plurality of transistors,
a first or more of the plurality of transistors include an oxide semiconductor, and
a second or more of the plurality of transistors include a polycrystalline semiconductor.

19. The display device of claim 11, wherein
the substrate further includes a base layer, and
the base layer includes glass.

20. The display device of claim 11, wherein
the second barrier layer directly contacts the semiconductor layer.
